(19) United States
(12) Patent Application Publication
(10) Pub. No.: US 2025/0299726 A1
(43) Pub. Date: Sep. 25, 2025

(54) MEMORY RELOCATION

(71) Applicant: Warren Fritz Kruger, Sunnyvale, CA (US)

(72) Inventor: Warren Fritz Kruger, Sunnyvale, CA (US)

(21) Appl. No.: 19/090,354

(22) Filed: Mar. 25, 2025

Related U.S. Application Data
(60) Provisional application No. 63/569,377, filed on Mar. 25, 2024.

(51) Int. Cl. G11C 11/4093; G02B 6/42; G02B 6/43; G11C 11/4096; H01L 25/16; H01L 25/18; H10B 12/00; H10B 80/00; H10F 55/20

(52) U.S. Cl. CPC G11C 11/4093; G02B 6/4293; G02B 6/43; H01L 25/167; H01L 25/18; H10B 12/50; H10B 80/00; H10F 55/20; G11C 11/4096

(57) ABSTRACT

Processors may interface with memory using microLED-based optical connections. MicroLEDs and photodetectors of the optical connections may be packaged outside of a package for the processor, packaged with a processor, or may be bonded to a surface of the processor. The optical connections may make use of interface chiplets. Some of the interface chiplets may include memory controller circuitry.

### CROSS-REFERENCE TO RELATED APPLICATIONS

This application claims the benefit of U.S. Provisional Patent Application No. 63/569,377, filed on Mar. 25, 2024, the disclosure of which is incorporated by reference herein.

### BACKGROUND OF THE INVENTION

Computer memory (e.g. DRAM) is a well-known bottleneck to computing speed. CPU core performance as well as storage and networking bandwidth are all increasing at a greater rate than DRAM bandwidth, so this already problematic wall only becomes more difficult as time goes by. There are two major approaches to increasing memory bandwidth per compute device: 1) scale-up by increasing the clock frequency of communication; and 2) scale-out by increasing the number of channels or the bus width of each channel. Both approaches are typically limited by the physical cost of communication between the processor and memory. Faster clocked physical layers are super-linear in power consumption, and require ever increasing precision of the traces used, leading to very expensive materials, high layer counts, and multiple design and test iterations in the processor package, motherboards, and sockets. Escaping wider or more numerous buses also grows the size and layer count of the package, motherboard, and sockets. We are constantly riding the edge of what is economically feasible and/or constructable with mass-manufacturing processes.

In order to reign in these costs, it may be preferred for memory to be placed as physically close to the processor as possible, e.g., DDR DIMMs are nestled as close as possible to the processor socket; LPDDR memory can be co-packaged with the processor itself; and in the most extreme case, HBM memory is placed on a silicon interposer flush against the processor. Not only are these approaches expensive in material and design time, but they introduce difficult thermal constraints as the more temperature-sensitive memory is very close to a very high-temperature processor. Another limitation of these approaches is that they naturally limit the capacity (bytes) of memory storage available. There is only a limited perimeter area around the processor, the closer the memory gets, the less area there is to place memory chips (not to mention all the other peripheral components and power supplies). HBM is as close as one can get, so it has to rely on even more expensive stacking of DRAM dies to achieve a reasonable capacity.

Unfortunately, that stacking scales poorly, in that yields plummet with the number of dies stacked; and dealing with the heat from the dies buried at the bottom of the stack even further exacerbates the thermal issues of being copackaged with the processor.

### BRIEF SUMMARY OF THE INVENTION

Some embodiments in accordance with aspects of the invention allow memory to be relocated away from the physical processor. A processor may be, for example, one or more central processing units (CPUs), graphical processing units (GPUs), data processing units (DPUs), tensor processing units (TPUs), and/or network processing units (NPUs). Some embodiments lead to the ability to greatly increase the capacity of a memory system. Some embodiments considerably ease thermal constraints. Some embodiments allow new platform form-factors.

Some embodiments use one or more arrays of microLEDs optically connected via one or more multi-core fiber bundles to one or more arrays of photodetectors (together a “MicroLED-based Optical Interconnect”) with a plurality of MicroLED-based Optical Interconnects between the main processor and its memory. A first set of the arrays of microLEDs and arrays of photodetectors of the MicroLED-based Optical Interconnect may be mounted to the processor or a chip or chiplet electrically coupled to the processor, and a second set of the arrays of microLEDs and arrays of photodetectors of the MicroLED-based Optical Interconnect may be mounted to a memory chip or a chip or chiplet electrically coupled to the memory chip. In some embodiments the photodetectors may be formed within the chips, instead of being mounted to the chips. Light from the first set of microLEDs is coupled to the second set of photodetectors by one or more multi-core fiber bundles, and light from the second set of microLEDs is coupled to the first set of photodetectors by the one or more multi-core fiber bundles, or other fiber bundles. With the light so coupled, communication can be performed between the processor and its memory using at least some optical links. Compared to existing electrical or optical approaches. in some embodiments a MicroLED-based Optical Interconnect has the trifecta of high bandwidth, low power, and low latency that allows for relocation of memory.

Some embodiments in accordance with some aspects of the invention provide an interface for coupling a processor to memory, comprising: a local microLED-based optical interconnect chiplet comprising a memory receiver interface and a first optical interface, the memory receiver interface configured to present itself to the processor as a memory device and to format signals from the processor for use by the first optical interface, the first optical interface configured to generate drive signals for driving first microLEDs based on the formatted signals from the memory receiver interface; the first microLEDs bonded to a surface of the local microLED-based optical interconnect chiplet; a remote microLED-based optical interconnect chiplet comprising a memory interface and a second optical interface, the second optical interface configured to process signals received by first photodetectors and provide the processed signals to the memory interface, the memory interface configured to communicate the processed signals with a memory device; the first photodetectors bonded to a surface of the remote microLED-based optical interconnect chiplet; and an optical fiber bundle having optical fibers coupling the first microLEDs and the first photodetectors. Some embodiments further comprise: second microLEDs bonded to the surface of the remote microLED-based optical interconnect chiplet; and second photodetectors bonded to the surface of the local microLED-based optical interconnect chiplet; and wherein the first optical interface is further configured to process signals received by the second photodetectors and provide the processed signals to the memory receiver interface, and wherein the memory receiver interface is further configured to format the processed signals for provision to the processor; and wherein the memory interface is further configured to format signals from the memory device for use by the second optical interface, and the second optical interface is further configured to generate drive signals for driving the second microLEDs based on the formatted signals from the memory interface. In some embodiments the local microLED-based optical interconnect chiplet is outside of a package of the processor. In some embodiments the local microLED-based optical interconnect chiplet is in a package of the processor. In some embodiments the local microLED-based optical interconnect chiplet is mounted to a same substrate as the processor.

Some embodiments in accordance with aspects of the invention provide an interface for coupling a processor to memory, comprising: a local microLED-based optical interconnect chiplet comprising a first interface and a first optical interface, the first interface being a configured to receive signals from a processor and to format signals from the processor for use by the first optical interface, the first optical interface configured to generate drive signals for driving first microLEDs based on the formatted signals from the memory receiver interface; the first microLEDs bonded to a surface of the local microLED-based optical interconnect chiplet; a remote microLED-based optical interconnect chiplet comprising a memory interface and a second optical interface, the second optical interface configured to process signals received by first photodetectors and provide the processed signals to the memory interface, the memory interface configured to serve as a memory controller and to communicate the processed signals with a memory device; the first photodetectors bonded to a surface of the remote microLED-based optical interconnect chiplet; and an optical fiber bundle having optical fibers coupling the first microLEDs and the first photodetectors. In some embodiments the local microLED-based optical interconnect chiplet is outside of a package of the processor. In some embodiments the local microLED-based optical interconnect chiplet is in a package of the processor. Some embodiments further comprise: second microLEDs bonded to the surface of the remote microLED-based optical interconnect chiplet; and second photodetectors bonded to the surface of the local microLED-based optical interconnect chiplet; and wherein the first optical interface is further configured to process signals received by the second photodetectors and provide the processed signals to the first interface, and wherein the first interface is further configured to format the processed signals for provision to the processor; and wherein the memory interface is further configured to format signals from the memory device for use by the second optical interface, and the second optical interface is further configured to generate drive signals for driving the second microLEDs based on the formatted signals from the memory interface.

These and other aspects of the invention are more thoroughly comprehended upon review of this disclosure.

### BRIEF DESCRIPTION OF THE FIGURES

FIG. 1 is a block diagram of a CPU interfaced to memory outside of a CPU package.

FIG. 2 is a block diagram of a Local LBIC and a Remote LBIC.

FIG. 3 is a block diagram of a CPU interfaced to memory outside of a CPU package, using LBICs that are in the CPU package.

FIG. 4 is a block diagram of a processor interfaced to high bandwidth memory (HBM) outside of a processor package, using LBICs that are in the processor package.

FIG. 5 is a block diagram with a processor configured to be interfaced to high bandwidth memory (HBM), but which uses MicroLED-based Optical Interconnects to interface with other types of memory.

FIG. 6 is a block diagram with a processor configured to interface with memory using a general interface and MicroLED-based Optical Interconnects.

FIG. 7 is a block diagram with a processor configured to be interfaced to memory by way of a general interface, and which uses MicroLED-based Optical Interconnects to interface with other types of memory.

FIG. 8 is a block diagram of a processor interfaced with memory, with Local LBICs integrated into a die of the processor.

### DETAILED DESCRIPTION

In some embodiments, CPUs in a CPU package are electrically coupled to one or more MicroLED-based Optical Interconnect interface chips (LBICs), memory chips are also electrically coupled to one or more LBICs, and the LBICs are optically coupled by one or more MicroLED-based Optical Interconnects. The LBICs to which the CPUs are coupled may include different circuitry than the LBICs to which the memory chips are coupled.

The MicroLED-based Optical Interconnects each comprise an array of microLEDs for generating light, an optical medium for transporting the microLED generated light, and an array of photodetectors for receiving the light transported over the optical medium. The optical medium may be a multi-core fiber bundle, and there may be a one-to-one-to-one relationship between each microLED, each core of the fiber bundle, and each photodetector. A microLED and a photodetector may therefore be at opposing ends of an optical fiber. Each LBIC may have one or more arrays of microLEDs and/or one or more arrays of photodetectors bonded to a surface of the LBIC, with the LBIC including microLED drive circuitry and/or receive circuitry for driving the microLEDs and processing photodetector signals, respectively.

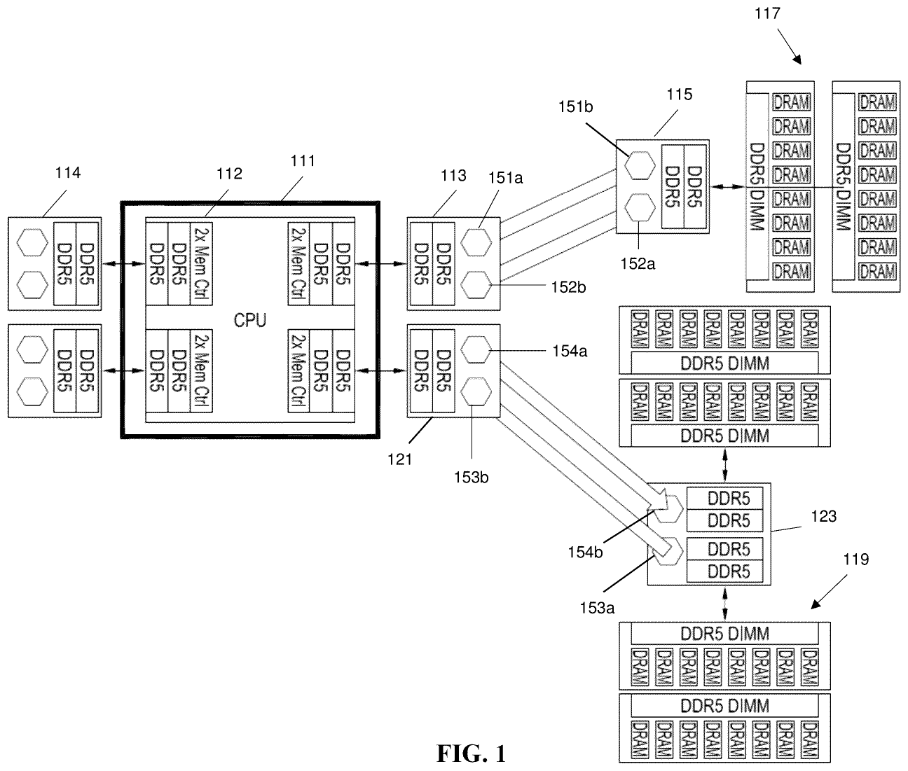

FIG. 1 is a block diagram of a CPU 112 interfaced to memory, e.g., memory 117, 119, outside of a CPU package 111. In the embodiment of FIG. 1, memory channels escape the processor package and socket on copper traces as in a typical system. Instead of the memory itself being located near the processor, small, packaged chips 113, 121, or LBICs, with a plurality of memory interfaces, e.g., memory interfaces 161a,b, and a plurality of optical interfaces and associated microLEDs and/or photodetectors, e.g., 151a, 152b, 154a, 153b, are located there. For clarity, these chips near the CPU may be referred to as the “Local LBIC” (Local MicroLED-based Optical Interconnect Interface chip). The memory interface on the Local LBIC is a “memory receiver” interface, which spoofs a traditional memory interface. This memory interface presents itself to the processor as an actual DRAM device. DRAM interfaces are physically asymmetric, and the DRAM is expected to be a synchronous slave device adhering to some standard; so this memory receiver preferably responds to the processor as if it were memory itself.

In some embodiments, the memory commands and data are taken from this memory receiver interface, provided to the optical interface, and transmitted via the MicroLED-based Optical Interconnect to a second packaged chip. The second chip may be considered a “Remote LBIC” (Remote MicroLED-based Optical Interconnect Interface chip). For both the Local LBIC and the Remote LBIC, the optical interface includes driver circuitry for driving the microLEDs of the MicroLED-based Optical Interconnect and receive processing circuitry for processing signals of the photodetectors of the MicroLED-based Optical Interconnect.

The second chip contains another optical interface, and a traditional memory interface which communicates with the DRAM. Signals from the DRAM may be handled by the traditional memory, provided to the optical interface of the Remote LBIC, and transmitted via the MicroLED-based Optical Interconnect to the Local LBIC.

In some embodiments, fundamentally, the system takes memory commands and data from/to the processor and replicates them remotely with no added processing. In some embodiments the Local LBIC, the MicroLED-based Optical Interconnect, and Remote LBIC, serve as a passthrough device, preferably transparent to the processor.

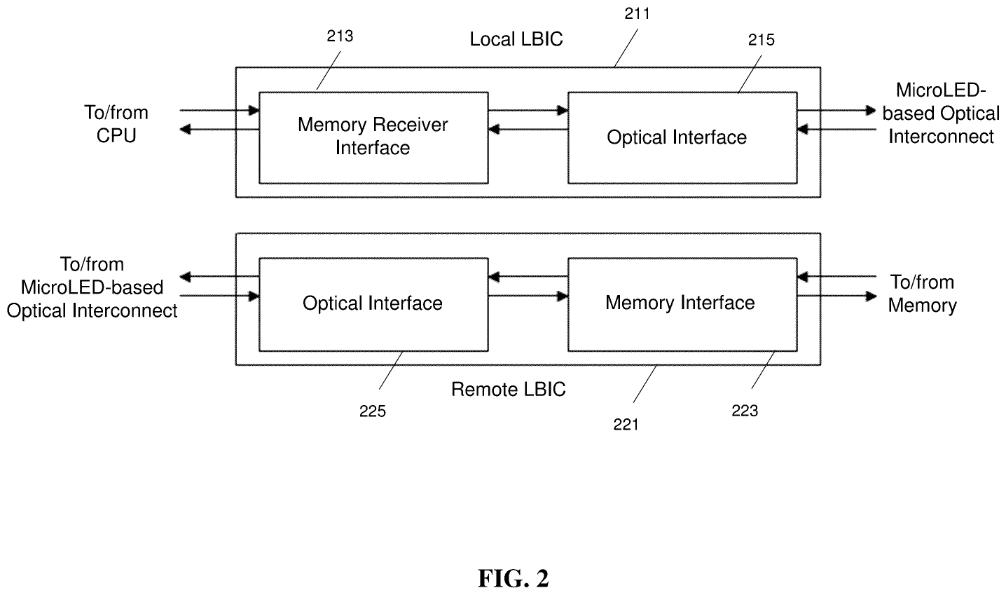

FIG. 2 is a block diagram of a Local LBIC 211 and a Remote LBIC 221. The Local LBIC is in electrical communication with processor, for example a CPU, and electrical communication with a MicroLED-based Optical Interconnect. The Remote LBIC is in electrical communication with memory, and electrical communication with the MicroLED-based Optical Interconnect. The Local LBIC and the Remote LBIC are at each end of the MicroLED-based Optical Interconnect, and therefore are in communication with each other.

The Local LBIC has a memory receiver interface 213 and an optical interface 215. The memory receiver interface of the Local LBIC receives signals from the CPU, and formats the signals for propagation use by the optical interface. The memory receiver interface also receives signals from the optical interface, and formats the signals for provision to the CPU. The optical interface generates drive signals for driving microLEDs of the MicroLED-based Optical Interconnect and/or processes signals from photodetectors of the MicroLED-based Optical Interconnect. The Remote LBIC also has a memory interface 223 and an optical interface 225. The memory interface of the Remote LBIC receives signals from the memory, and formats the signals for propagation use by the optical interface. The memory interface also receives signals from the optical interface, and formats the signals for provision to the memory. The optical interface generates drive signals for driving microLEDs of the MicroLED-based Optical Interconnect and/or processes signals from photodetectors of the MicroLED-based Optical Interconnect. In some embodiments, the Local LBIC and the Remote LBIC may each have a same chiplet design, with the chiplet design allowing for configuration at boot-time to perform as either a Local LBIC or a Remote LBIC.

In some such embodiments the memory receiver interface and/or memory interface passes information from each of its inputs to the optical interface. In some embodiments each input to the memory receiver interface is coupled or mapped to a corresponding processor pin and/or each input to the memory interface is coupled or mapped to a corresponding memory pin. In some embodiments the optical interface drives microLED(s) with information of the input over an optical lane, which may be a single fiber of a fiber bundle or sub-bundle. In some embodiments the memory receiver interface may combine multiple inputs that comprise a single signal or lane into a single output to the optical interface and/or the memory interface may combine multiple inputs that comprise a single signal or lane into a single output to the optical interface. For example, the memory receiver interface may receive a signal as a differential signal, provided by two processor pins, with the memory interface providing a single ended signal to the optical interface. In such embodiments, the memory interface may receive one more single ended signals from the optical interface and convert those signals to differential signals for provision to the processor, for situations in which the processor includes multiple pins for receiving the differential signals.

In some embodiments the memory interface may group signals received from the processor into packets, with the packets provided to the optical interface for transmission by microLEDs. In such embodiments the memory interface may degroup packetized signals from the MicroLED-based Optical Interconnect interface, for provision to the processor.

Advantages of this embodiment of memory relocation may include, for some or various embodiments, one, some, or all of: no change to the processor or its package (existing processors can be used); and/or new form-factors are made possible as memory is not physically constrained to be processor adjacent; in most cases, the motherboard PCB layout near the processor will become simpler as there is reduced or no fan-out of traces to a wide number of memory chips—which may result in lower power, faster turn, and possibly lower layer count and cheaper motherboard material; the memory can be moved to a better thermal environment, even having its own subassembly, external chassis, and/or cooling systems (separate temperature control)—in some embodiments the memory may be located centimeters away from the processor, and in some embodiments between 10 and 20 centimeters from the processor, and in some embodiments more than 20 centimeters from the processor; that memory capacity can be substantially increased by increasing the channel count at the memory end of the connection; and escaping more memory channels from the processor on copper traces may be economically prohibitive, and/or non-manufacturable, and/or the data transmission rate may suffer dramatically due to signal integrity issues.

A disadvantage of these embodiments over traditional memory placement may be that the total system power may increase slightly as the overhead of the MicroLED-based Optical Interconnect communication is added.

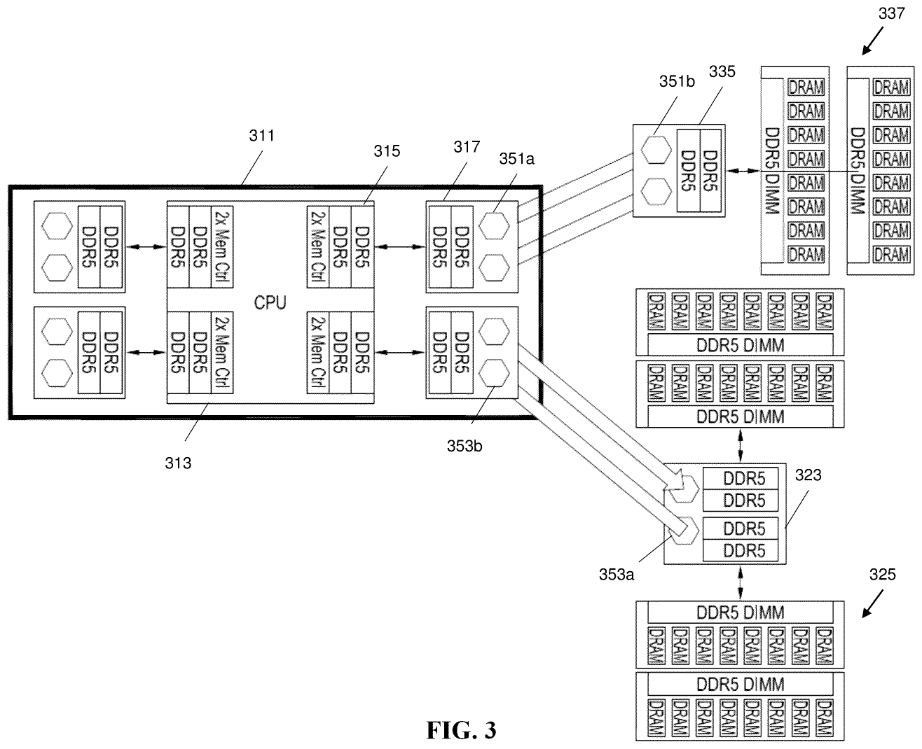

FIG. 3 is a block diagram of a CPU interfaced to memory outside of a CPU package, using LBICs that are in the CPU package. The embodiment FIG. 3 is similar to the embodiment of FIG. 2, except that the Local LBIC is co-packaged with the processor instead of having its own package on the motherboard. Accordingly, in FIG. 3, a CPU package 311 includes a CPU 313 and Local LBICs, e.g., Local LBIC 317. The CPU includes memory interfaces, e.g., memory interface 315, which is in communication with the Local LBICs. MicroLEDs, e.g., MicroLEDs 351a, and photodetectors, e.g., photodetectors 353b, are bonded to the Local LBICs. The MicroLEDs and the photodetectors are part of a MicroLED-based Optical Interconnect coupling the Local LBICs with Remote LBICs, e.g., Remote LBICs 323, 335. MicroLEDs, e.g., MicroLEDs 353a, and photodetectors, e.g., photodetectors 351b, are bonded to the Remote LBICs. The Remote LBICs are in communication with memory, e.g., memory 325, 337.

In some embodiments the MicroLED-based Optical Interconnects have one or more small form-factor pluggable interfaces directly to this package. The pluggable interface may provide a port to receive a fiber bundle in a side wall of the CPU package, and possibly coupling optics. Alternatively, the pluggable interface may provide a port to receive a fiber bundle on a side of the CPU package mounted to a board, substrate, or interposer, along with a corresponding aperture in the board, substrate, or interposer. This embodiment may have the same advantages as the embodiment of FIG. 1, but may substantially improve ease of the layout near the processor. Since the memory traces no longer need to escape the processor package to the motherboard in some embodiments, the package substrate layer count and material cost can be greatly reduced. Additionally, the number of pins/pads/balls on the package may be greatly reduced (the DRAM interface is typically much greater than half the pinout on a processor); lower pin count brings higher reliability, cheaper sockets and/or better solderability, simpler mechanical assemblies (less pressure required), and/or more room for power components and power distribution and to the processor itself.

The embodiment of FIG. 3 could also result in a lower total system power. As the memory channel from the processor is such a short, simple reach to the memory receiver chip, that interface could be tuned to a much lower power. The processor also has a better power integrity environment, leading to higher efficiency in the supply. And the DRAM interfaces from the Remote LBIC are easier to escape and have a better power and signal integrity environment, needing less power than it would if co-located with the processor. In some embodiments, the additional power of the MicroLED-based Optical Interconnect communication is less than the power savings from these, resulting in net lower system power.

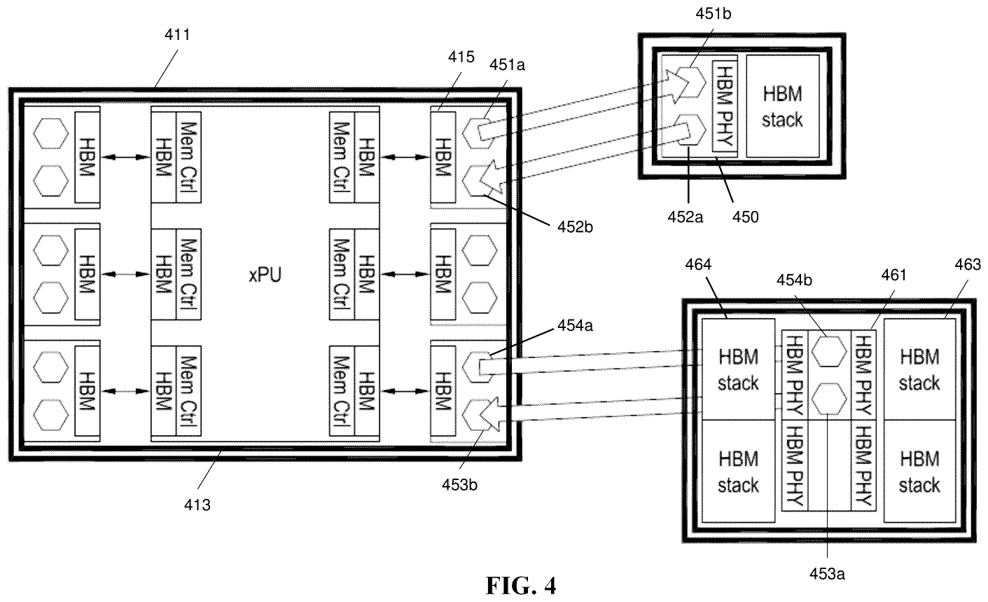

FIG. 4 is a block diagram of a processor interfaced to high bandwidth memory (HBM) outside of a processor package, using LBICs that are in the processor package. The embodiment FIG. 4 is similar to the embodiment of FIG. 3. In the embodiment of FIG. 4, the processor is configured to interface with HBM, and the Remote LBIC is interfaced with, and co-packaged with in some embodiments, one or more HBM stacks. Accordingly, in FIG. 4, a processor package 411 includes a processor 413 and Local LBICs, e.g., Local LBIC 415. The processor includes HBM interfaces in communication with the Local LBICs. MicroLEDs, e.g., MicroLEDs 451a, 454a and photodetectors, e.g., photodetectors 452b, 453b are bonded to the Local LBICs. The MicroLEDs and the photodetectors are part of a MicroLED-based Optical Interconnect coupling the Local LBICs with Remote LBICs, e.g., Remote LBICs 450, 461. MicroLEDs, e.g., MicroLEDs 452a, 453a, and photodetectors, e.g., photodetectors 451b, 454b, are bonded to the Remote LBICs. The Remote LBICs are shown in FIG. 4 as being on a same substrate as one or more HBM stacks, and in a same package as their associated HBM stacks. For example, Remote LBIC 461 is on a same substrate and in a same package as HBM stack 463. The substrate may be, for example, a silicon interposer. The Remote LBICs are in communication with their associated HBM Stacks. For example, Remote LBIC 461 interfaces with both HBM stack 463 and HBM stack 464.

The embodiment of FIG. 4 allows for replacement of HBM (High Bandwidth Memory) stacks located near a processor with Local LBICs, allowing the HBM stacks to be relocated away from the processor. In some embodiments the Local LBICs may be within the CPU package, as illustrated in FIG. 4. In some embodiments the Local LBICs may be outside the CPU package, for example as discussed with respect to the embodiment of FIG. 1. The embodiment of FIG. 4 generally has the same advantages as that of the embodiment of FIG. 1, and particularly in that it may allow for increasing of a channel count at a memory end of a connection between a processor and memory. HBM, as designed, is generally limited to being placed flush against the processor die; so the capacity is constrained by the perimeter of the processor times the height of the HBM stack. The HBM stack is generally limited to about 12 die for yield and thermal reasons, and the perimeter of a reticle-sized processor generally only allows for about 6 stacks. With use of memory relocation, the Remote LBIC can address multiple HBM stacks, for example possibly increasing the capacity by 2 to 4 times. This is particularly valuable for large AI models where GPU/TPU processors generally prefer the very high bandwidth provided by HBM, but performance is hindered by the limited capacity due to physical constraint, often leading to stranding of compute because the model is necessarily spread out across many processors just to fit. The scheme also may enable multi-tenancy, or a mixture of experts type of AI models, where several models reside in memory, but only a subset is used on any given batch.

That the HBM stacks may be in cooler environment away from the processor may be a more substantial advantage, as cooling the HBM is a very difficult constraint, as HBM may prefer to operate in environments <<85 C, whereas the typical high-wattage processor can often reach 105 C. A separate thermal environment for HBM allows the HBM to run much cooler, relax the refresh rate and produce fewer errors/bit-flips.

A possible disadvantage of the embodiment of FIG. 4 is potential increased power requirements, as it has at least 2× the number of HBM interfaces, as well as the MicroLED-based Optical Interconnect.

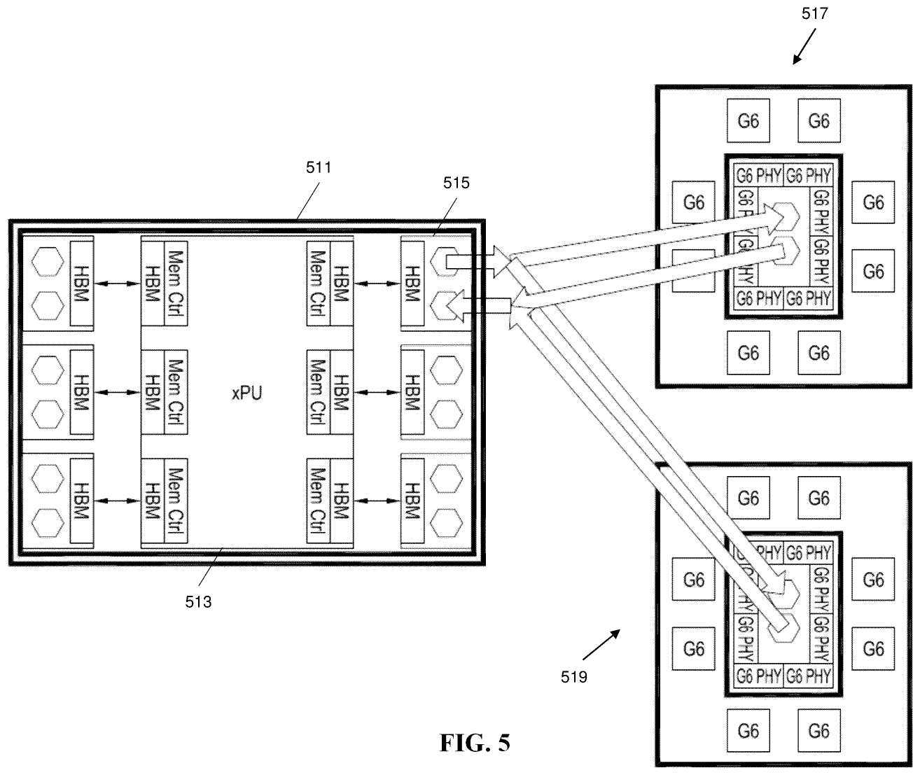

FIG. 5 is a block diagram with a processor 513 configured to be interfaced to high bandwidth memory (HBM), but which uses MicroLED-based Optical Interconnects to interface with other types of memory. HBM was designed specifically to be placed next to the processor for bandwidth reasons. Use of MicroLED-based Optical Interconnects and Local and Remote LBICs can physically relocate memory of this bandwidth, reducing or eliminating any need for the complexity and cost of HBM in various embodiments. In the embodiment of FIG. 5, a Local LBIC, e.g., Local LBIC 515, replaces an HBM stack in the processor package 511 (as in the embodiment of FIG. 4), but the remote memory is no longer HBM. Instead, the remote memory 517, 519 is some other memory technology. FIG. 5 shows the other memory technology as GDDR6, but in other embodiments other commodity or custom memory (even SRAM in some embodiments) is substituted.

Also in FIG. 5, fiber bundles of the MicroLED-based Optical Interconnect have a fan-out ‘Y’ connections, where a single bundle on one end is split out into a plurality of bundles on the other end. In some embodiments the single bundle on the one end is a fiber bundle, and the plurality of bundles on the other end are sub-bundles of the fiber bundle.

FIG. 5 shows eight sub-channels of one HBM stack being split out to eight independent DRAM modules made from JEDEC standard GDDR6 devices. With no loss of generality, the number of modules, the number and type of memory on those modules, and the mapping to HBM channels can be varied to suit the application, with in some embodiments the intention that the combined bandwidth of those modules adds up to approximately the Local LBIC HBM interface bandwidth. In various embodiments, these modules may be of any form-factor and may be built as a set of modules with or without the MicroLED-based Optical Interconnect fan-out directly integrated. The advantages may be the same as with respect to the embodiments of FIGS. 1 and 4, but particularly with respect to an increase in memory capacity, as capacity can now be increased by 8 to 32 times or more, without sacrificing bandwidth. System power may increased, but that is natural due to the nature of the total amount of memory capacity added.

The memory modules may also have form-factors with substantial improvement in the thermal and power-delivery environments (e.g., modules could contain their own power supply circuits, and/or be built very compactly with integrated liquid cooling).

A possible disadvantage of the approach of the embodiment of FIG. 5 is that when not using HBM, the number of DRAM dies to achieve HBM-like bandwidth may be substantial. So it may be necessarily more expensive for the increased amount of DRAM silicon. One possibility to ameliorate this would be to have the local LBIC be the same for the embodiments of FIGS. 4 and 5, and allow the customer to populate the corresponding cable, and in some embodiments modules may be either HBM or another memory module.

The embodiments above are generally devised to work with a processor designed to use existing standard memories. This may allow the processor owner to prototype this memory relocation with existing processors; and to de-risk production of memory relocation as they can always fall back to the traditional memory population physically next to the processor. Without loss of generality, in some embodiments packaging is in various embodiments multi-die on organic substrate, or 2.5D on Silicon interposers, or proprietary multi-die interconnect bridges. The Local LBIC could also be integrated into an active interposer in some embodiments.

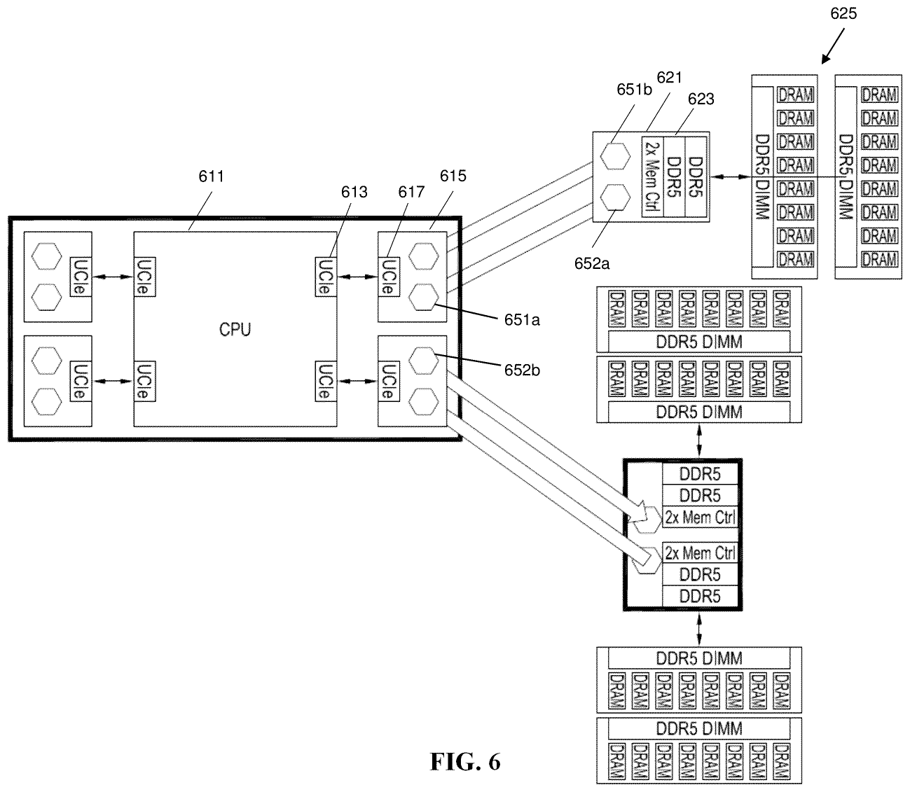

The following embodiments of FIGS. 6-8 have a modified processor die. The embodiments could use open or proprietary protocols, or any other flow-control or packetized interface sending memory requests over UCIe, BoW, PCIe or similar physical layers. The memory controller logic could also be relocated to the Remote LBIC. In these cases, the Local and Remote LBIC may be different designs.

FIG. 6 is a block diagram of a processor configured to interface with memory, e.g., memory 625, using a general interface and MicroLED-based Optical Interconnects. In this embodiment, the Local LBIC 615 is co-packaged with the processor 611, and the processor uses a custom or standard (e.g. UCIe or BoW) interface 613 to an interface 617 of the Local LBIC to communicate memory commands (e.g., not a standard memory chip interface). The commands and data are sent by the Local LBIC via a MicroLED-based Optical Interconnect to a Remote LBIC 621. The MicroLED-based Optical Interconnect includes, as before, LBIC-bonded microLEDs, e.g., microLEDs 651a, 652a, and LBIC-bonded photodetectors, e.g., photodetectors 651b, 652b, coupled by a fiber bundle. At the Remote LBIC there is a plurality of memory controllers and memory PHYs (DDR5 DIMMs in this example, but could be LPDDR, GDDR or HBM). Some or all the memory controller logic could be located in the Local LBIC, in some embodiments. In some embodiments, the memory controller logic resides in the Remote LBIC, for example to be as close to the PHY as possible.

Advantages may include: new form-factors are made possible as memory is not physically constrained to be processor adjacent; in most cases, the motherboard PCB layout near the processor will become simpler as there is no fan-out of traces to a wide number of memory chips; power delivery to the local LBIC should also be substantially easier than to memory PHYs; may results in lower power, faster turns, and possibly lower layer count and cheaper motherboard material; the memory can be moved to a better thermal environment, even having its own subassembly, external chassis, and/or cooling systems (separate temperature control); memory capacity can be substantially increased by increasing the channel count at the memory end of the connection (see lower example in diagram); escaping more memory channels from the processor on copper traces would be economically prohibitive, and/or non-manufacturable, and/or the data transmission rate would suffer dramatically due to signal integrity issues; and system power may be slightly reduced, as the remote memory could be designed to have a much better channel than running it directly from the processor, so PHYs can be tuned to lower power.

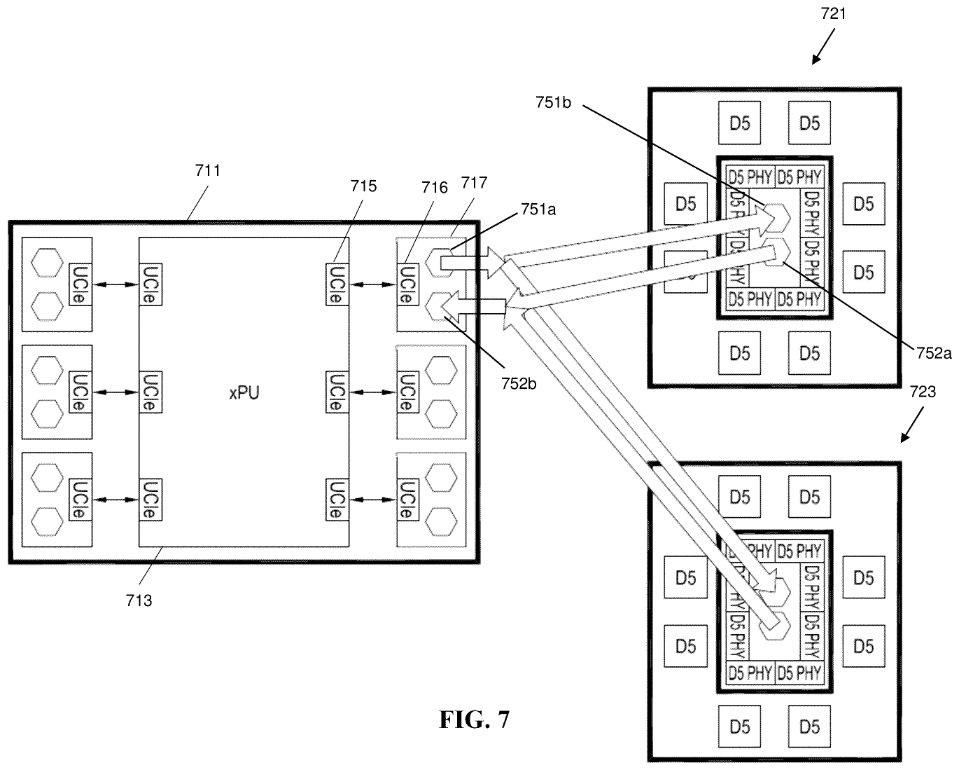

FIG. 7 is a block diagram with a processor configured to be interfaced to memory by way of a general interface, and which uses MicroLED-based Optical Interconnects to interface with other types of memory. In FIG. 7, a processor 713 and Local LBICs 717 are co-packaged in a package 711. The processor and the Local LBICs each have a general interface 715, 716, shown as a UCIe interface in FIG. 7, for communication between the processor and the Local LBICs. The local LBICs have microLEDs and photodetectors bonded to them, e.g., microLEDs 751a and photodetectors 752b, for communication over a fiber bundle or sub-bundle with microLEDs, e.g. microLEDs 752a, and photodetectors, e.g., photodetectors 751b, at Remote LBICs located with different memory modules 721, 723. A fiber bundle from the Local LBIC may fan out to Remote LBICs at different memory modules 721, 723.

The embodiment of FIG. 7 is similar to that of FIG. 6, but the embodiment of FIG. 7 uses new memory modules rather than standard memory interfaces such as DIMMs, similar to those discussed with respect to the embodiment of FIG. 5. Advantages are similar to those of the embodiment of FIG. 6. In this example of FIG. 7, the UCIe interface (without loss of generality) can be comprised of many sub-channels, and each subchannel can address any remote memory (or not). As in the embodiment of FIG. 6, the memory controller is likely to reside on the Remote LBIC. Because the physical interface to the processor can have a much lower beachfront per bandwidth metric than other memory technology, this embodiment can result in both a much higher bandwidth and much higher capacity than other memory technologies (HBM, DDR, etc.).

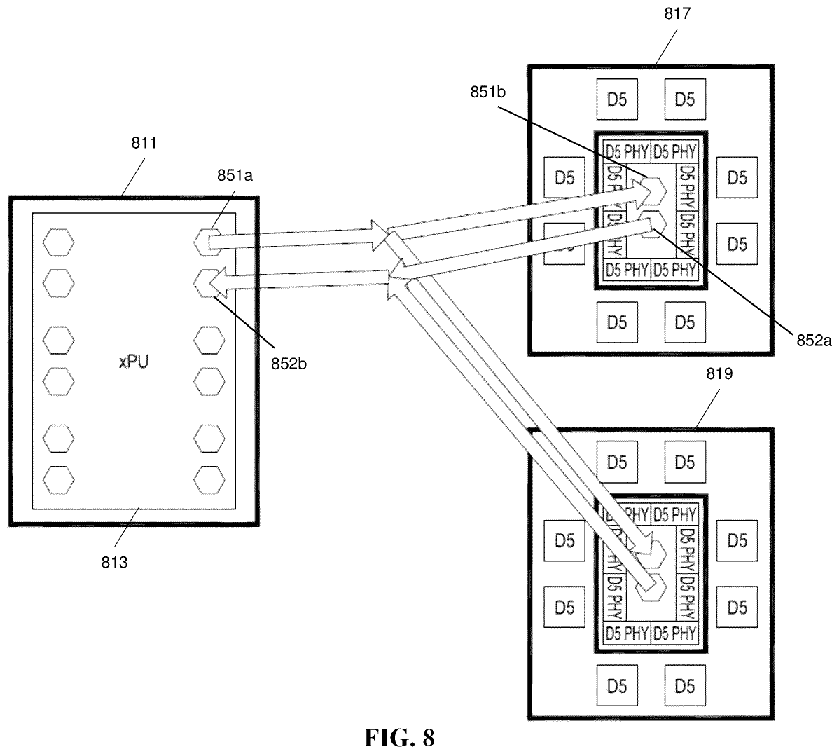

FIG. 8 is a block diagram of a processor interfaced with memory, with Local LBICs integrated into a die of the processor. In FIG. 8, a processor 813 is in a package 811 for the processor. The processor incorporates circuitry as generally discussed with respect to the Local LBICs. MicroLEDs, e.g., microLEDs 851a, and photodetectors, e.g., photodetectors 852b, are bonded onto a surface of the processor. The microLEDs and photodetectors on the processor are part of MicroLED-based Optical Interconnects, which couple the processor to modules 817, 819 for memory. The modules each include Remote LBICs, having corresponding microLEDs, e.g. microLEDs 852a, and photodetectors, e.g., photodetectors 851b, of the MicroLED-based Optical Interconnects.

The embodiment of FIG. 8 is similar to that of FIG. 7, except that the Local LBIC is integrated directly into the processor die. This should result in the lowest latency; and simplifies packaging as no Local LBIC chiplet is, in some embodiments, integrated (no interposers or multi-die packaging). The Local LBIC may provided as hard or soft IP for inclusion in the processor.to the In some embodiments the Local LBIC communicates with the processor with custom or standard logic interfaces (e.g. ARM AMBA). LED/photodetector arrays of any size can be placed wherever convenient on the processor die, freeing the design from beachfront limitations of bandwidth (although thermals/heatsinking of the processor is taken into account in various embodiments). In various embodiments the remote LBIC addresses standard memory form factors such as DIMMs, or new modules with any memory technology (e.g. DDR, LPDDR, GDDR, HBM). Here again, in some embodiments the memory controller resides primarily on the remote LBIC.

Without loss of generality, Local LBIC packaging may variously be on multi-die on organic substrate, 2.5 D on Silicon interposers, proprietary multi-die interconnect bridges, or wafer-level fan-out (e.g. InFO, LiFO, FPWLP, FOPLP). In some embodiments the Local LBIC is integrated directly into an active interposer.

Various encoding/decoding permutations are discussed below.

Without a memory controller in the processor, and the processor having a pinout intended to connect to a transport layer (e.g. UCIe, PCIe, BoW), or some natural logic interface (e.g. AMBA, ready/valid, credit/debit): The memory controller may be contained entirely on the local or the remote LBIC, or it may split functions between the two; For example, on the local LBIC, the address can be decoded into a physical address (channel, rank, bank, row, column), address remapping applied, scrambling applied to the data, and the transaction re-encoded with LBIC native ECC, and is sent to the selected remote LBIC; On that remote LBIC, the ECC and scrambling is decoded, and the transaction with its new physical address is sent to the targeted memory controller; The native transaction may be sent unencoded over the LBIC link. The native transaction may be encoded over the LBIC links (in some embodiments resulting in a concatenated code if the native transaction is already encoded in some way); If the native transaction is encoded (e.g. a CXL flit), it may be decoded and/or inspected on the local LBIC, re-encoded into some native LBIC format, sent over the link, decoded on the remote LBIC and finally re-encoded to output the processor native format again. For example, a UCIe interface transmits a 68 B PCIe flit to the local LBIC. That local LBIC is connected to a plurality of remote LBICs. The local LBIC decodes the 68 B flit to examine the destination address and re-encodes the transaction with some LBIC-native FEC, and sends it across the link to the appropriate remote LBIC. The remote LBIC decodes the FEC, re-encodes to a conformant 68B PCIe flit, and sends it out the remote UCIe interface-and the decode and encode steps on either the remote and/or local LBIC may be optimized into a single logic block; For transactions that contain a memory command directly (e.g. ACT, PRE, RD, WR), either the local or remote LBIC implements a memory controller that enforces relative timing between the commands on the output of the remote LBIC; For transactions that do not contain memory commands (e.g. address/data/vld), the transaction may be decoded to a memory physical address (e.g. channel, rank, bank, row, column) on either the local or remote LBIC; Different coherency, consistency, and ordering models may be required by the system and the LBIC memory controller may re-order and/or cache these transactions subject to those constraints; The memory controller may implement error correction or detection either hidden or exposed to the processor, and a plurality of ECC may be applied to any of links, internal LBIC logic and structures, and/or stored in memory (either serially, and/or in parallel with additional memory devices); and error propagation from any stage in the LBIC or memory may be implemented by poisoning the transaction code in return data or acknowledgements to the processor.

During the encoding or decoding of the transaction, regardless of the type, the transaction may be modified in various ways: Adjusting for different DRAM requirements (e.g. processor thinks it is communicating to one type of DRAM (e.g. HBM), and the remote LBIC is actually communicating with a different type of DRAM (e.g. DDR5), including a different number of channels, a different memory size or shape (rows/columns/ranks), different timing parameters (adjusting transaction issuance time between constrained transactions); remapping physical or logical addresses; remapping, changing, or ignoring sideband or register writes, e.g., MSR transactions; Changing clock domains/frequencies; Error correction and/or detection bits may be calculated and sent/received, either serially or in parallel with additional memory; Spare lanes may be used for redundancy/yield/Signal Integrity/Power Integrity and spare lanes to use may be identified at manufacture, power-on, reset, boot, initialization and/or run-time; Bits may be scrambled/descrambled in space and/or time for Signal Integrity and/or Power Integrity purposes; Power states may be implemented to change the encoding scheme depending on the bandwidth, and/or latency demands of the traffic, and/or sideband signals; the LBICs may include table walkers, processors, or other logic structures to implement security policies. e.g., Logical address remapping and validation (e.g. MMUs or segments), Firewalls (e.g. filtering by requestor, target address, segment, security bits set in the transaction, or transaction rate limits).

Various memory related signals are discussed below. LBICs, or circuitry interfaced with or replacing functions of the LBICs, may use or process the signals in the manners discussed below.

Clock (CK)—Address, Command, and/or Data clocks. These signals are typically differential when provided electrically. Some embodiments encode the signals directly as differential. Some embodiments capture the signals, for example with a comparator, and send the signals as single ended. Some embodiments reencode the single ended signals as differential signals to output on the remote LBI. Some embodiments multiplex the signals to separate lanes for spares (special spare lanes for clocks as opposed to data signals, for example). Some embodiments do not transmit the clock signal, with instead the clock signal regenerated on the remote LBIC by a Clock Data Recovery (CDR) mechanism by inspecting data transitions. In some embodiments the clock can also be passed through a PLL to reduce jitter on either or both the local and remote LBIC.

Data (DQ)—

Writes: DQs can be transmitted directly (clockless), or captured/re-timed with TxStrobe on either the local or remote LBIC.

Reads: DQs can be transmitted directly (clockless), or captured/re-timed with RxStrobe on either the local or remote LBIC.

Reads or Writes: In some embodiments data may be scrambled and/or ECC/Parity encoded to improve the error rate. Data may also be encoded for DC balance, run length, and/or transition density (e.g. 8 b/10 b and 64 b/66 b).

Address (R, C)—Address can be transmitted directly (clockless), or captured/re-timed with an Address Clock. In some embodiments address may be scrambled and/or ECC/Parity encoded to improve the error rate. Address may also be encoded for DC balance, run length, and/or transition density (e.g. 8 b/10 b and 64 b/66 b). Address may be modified to improve performance, lower power, or address different DRAM configurations than the processor memory controller is expecting (e.g. rank or row bits can be re-encoded as channel bits if the remote LBIC is addressing more memory channels than the processor)—this modification can occur on the local or remote LBIC (at the encode or decode stage)

Clock Enable (CKE)—Enable can be transmitted directly (clockless), or captured/re-timed with the Address/Command Clock on either the local LBIC, remote LBIC, or both. CKE also initiates low power states in the DRAM; so the local and remote LBIC can inspect the status of CKE and address/command bits with a state machine that initiates various lower power states in the local LBIC, remote LBIC, or both.

TxClk/TxStrobe—TxStrobe can be transmitted directly (clockless), or used to capture/re-time Tx data on either the local LBIC, remote LBIC, or both. If strobe is not transmitted across the link, it can be regenerated from the TxClk and a delayline or DLL on the remote LBIC for output.

RxClk/RxStrobe—RxStrobe can be transmitted directly (clockless), or used to capture/re-time Rx data on either the remote, local LBIC, or both. If strobe is not transmitted across the link, it can be regenerated from the RxClk on the remote LBIC for output.

Data Bus Inversion (DBI)—Similar to DQ Writes, DBI can be transmitted directly (clockless), or captured/re-timed with TxStrobe on either the local or remote LBIC. Additionally, DBI+DQ can be decoded on the local LBIC, and DBI not transmitted across the link; it can then be regenerated/encoded by inspecting the DQ word on the remote LBIC. If the processor and remote memory have different numbers of DBI pins (including zero), or different encodings, either the local or remote LBIC can decode/re-encode as appropriate.

Data Mask (DM)—Similar to DQ Writes, DM can be transmitted directly (clockless), or captured/re-timed by the TxStrobe on either the local or remote LBIC. Additionally, If all words addressed to a particular remote memory channel are masked, the local or remote LBIC can drop the transaction.

ECC/Parity—Similar to DQ Writes, ECC/Parity can be transmitted directly (clockless), or captured/re-timed by the TxStrobe on either the local or remote LBIC. Additionally, ECC/Parity can be decoded on the local LBIC, not sent across the link, and regenerated on the remote LBIC by inspecting the DQ bits. Further, additional/different ECC/Parity bits can be added to the link in parallel or serial to improve the error rate of the link. This could be as a concatenated code added to some or all of the DQ, DM, DBI, and ECC bits. Or some or all of the DQ/DBI/ECC bits can be decoded in the local LBIC, and a new ECC/Parity encoding could be generated to transmit across the link, decoded on the remote LBIC. In the Rx direction, the link can add ECC/Parity encoded by the remote LBIC and decoded by the local LBIC.

Error (AERR, DERR)—Similar to DQ Reads, ERR can be transmitted directly (clockless), or captured/re-timed with RxStrobe on either the local or remote LBIC. The ERR signal may also be logically combined with the output of any LBIC-internal decoding or state inspection that can generate an error.

Reset (RST)—RST can be transmitted directly (clockless), or captured/re-timed with some always-on clock (generated by the processor or inside the LBIC) on either the local or remote LBIC.

Temperature (e.g. TEMP, CATRIP)—similar to RST, TEMP can be transmitted directly (clockless), or captured/re-timed with some always-on clock (generated by the processor or inside the LBIC) on either the local or remote LBIC.

IEEE1500/JTAG (e.g. WRCK, WRST, SELECTWIR, SHIFTWR, CAPTUREWR, UPDATEWR, WSI, WSO)—JTAG signals can be transmitted directly (clockless), or captured/re-timed with the JTAG clock, on either the local or remote LBIC. Additionally, the JTAG map may include the some or all of the local and/or remote LBIC as addressable sub-chains. The local and/or remote LBIC may also have separate JTAG ports exposed to the system/control plane.

Sideband (e.g. I2C, UART, straps, vendor-specific)—Sideband signals can be transmitted directly (clockless), or captured/re-timed with some always-on clock (either internal or external), on either the local or remote LBIC. Alternatively, a sideband signal may be decoded on the local LBIC, and sent over some link to the remote LBIC in a different format where it is decoded. Any given sideband communication can multiplexed onto other signal channels, or can have it's own dedicated link (e.g. receive and decode an UART word on the local LBIC, re-encode with ECC, send over a dedicated link, decode ECC, and re-form the UART signal to be output by the remote LBIC). A decoded sideband signal may also mux into the control plane of the local and/or remote LBIC, similar to JTAG (e.g. receive and decode an UART word on the local LBIC, inspect the address and determine it is intended targeted at the local LBIC register space, then send the transaction to the determined register, and do not forward the transaction across the link). Sideband signals may be unidirectional or bidirectional, and may originate at either the local or remote LBIC (either internally or from external pins on the LBIC). Known static signals (e.g. straps) may captured at reset or initialization time, multiplexed over some signal lane(s), then captured, stored and output on the other end (so no need to re-send or dedicate a link).

Spares (RD, RC, RR)—

Similar to DQ Reads and Writes, spares for DQ, DBI, DM can be transmitted directly (clockless), or captured/re-timed with TxStrobe or RxStrobe on either the local or remote LBIC.

Clocks and Strobes have a different set of spares from the signal pin spares to accommodate dedicated wiring for clock trees.

Sideband signals could also have a different set of spares as well.

Although the inventions have been discussed with respect to various embodiments, it should be recognized that the inventions comprise the novel and non-obvious claims supported by this disclosure.

What is claimed is:

1. An interface for coupling a processor to memory, comprising:
a local microLED-based optical interconnect chiplet comprising a memory receiver interface and a first optical interface, the memory receiver interface configured to present itself to the processor as a memory device and to format signals from the processor for use by the first optical interface, the first optical interface configured to generate drive signals for driving first microLEDs based on the formatted signals from the memory receiver interface;
the first microLEDs bonded to a surface of the local microLED-based optical interconnect chiplet;
a remote microLED-based optical interconnect chiplet comprising a memory interface and a second optical interface, the second optical interface configured to process signals received by first photodetectors and provide the processed signals to the memory interface, the memory interface configured to communicate the processed signals with a memory device;
the first photodetectors bonded to a surface of the remote microLED-based optical interconnect chiplet; and
an optical fiber bundle having optical fibers coupling the first microLEDs and the first photodetectors.

2. The interface for coupling a processor to memory of claim 1, further comprising:
second microLEDs bonded to the surface of the remote microLED-based optical interconnect chiplet; and
second photodetectors bonded to the surface of the local microLED-based optical interconnect chiplet; and
wherein the first optical interface is further configured to process signals received by the second photodetectors and provide the processed signals to the memory receiver interface, and wherein the memory receiver interface is further configured to format the processed signals for provision to the processor; and
wherein the memory interface is further configured to format signals from the memory device for use by the second optical interface, and the second optical interface is further configured to generate drive signals for driving the second microLEDs based on the formatted signals from the memory interface.

3. The interface for coupling a processor to memory of claim 1, wherein the local microLED-based optical interconnect chiplet is outside of a package of the processor.

4. The interface for coupling a processor to memory of claim 1, wherein the local microLED-based optical interconnect chiplet is in a package of the processor.

5. The interface for coupling a processor to memory of claim 1, wherein the local microLED-based optical interconnect chiplet is mounted to a same substrate as the processor.

6. The interface for coupling a processor to memory of claim 2, wherein the local microLED-based optical interconnect chiplet is outside of a package of the processor.

7. The interface for coupling a processor to memory of claim 2, wherein the local microLED-based optical interconnect chiplet is in a package of the processor.

8. The interface for coupling a processor to memory of claim 2, wherein the local microLED-based optical interconnect chiplet is mounted to a same substrate as the processor.

9. An interface for coupling a processor to memory, comprising:
a local microLED-based optical interconnect chiplet comprising a first interface and a first optical interface, the first interface being a configured to receive signals from a processor and to format signals from the processor for use by the first optical interface, the first optical interface configured to generate drive signals for driving first microLEDs based on the formatted signals from the memory receiver interface;
the first microLEDs bonded to a surface of the local microLED-based optical interconnect chiplet;
a remote microLED-based optical interconnect chiplet comprising a memory interface and a second optical interface, the second optical interface configured to process signals received by first photodetectors and provide the processed signals to the memory interface, the memory interface configured to serve as a memory controller and to communicate the processed signals with a memory device;
the first photodetectors bonded to a surface of the remote microLED-based optical interconnect chiplet; and
an optical fiber bundle having optical fibers coupling the first microLEDs and the first photodetectors.

10. The interface for coupling a processor to memory of claim 9, wherein the local microLED-based optical interconnect chiplet is outside of a package of the processor.

11. The interface for coupling a processor to memory of claim 9, wherein the local microLED-based optical interconnect chiplet is in a package of the processor.

12. The interface for coupling a processor to memory of claim 9, further comprising:
second microLEDs bonded to the surface of the remote microLED-based optical interconnect chiplet; and
second photodetectors bonded to the surface of the local microLED-based optical interconnect chiplet; and
wherein the first optical interface is further configured to process signals received by the second photodetectors and provide the processed signals to the first interface, and wherein the first interface is further configured to format the processed signals for provision to the processor; and
wherein the memory interface is further configured to format signals from the memory device for use by the second optical interface, and the second optical interface is further configured to generate drive signals for driving the second microLEDs based on the formatted signals from the memory interface.
